(19) United States
(12) Patent Application Publication
(10) Pub. No.: US 2026/0255737 A1
(43) Pub. Date: Aug. 27, 2026

(54) SOLUTION PROCESSABLE RHENIUM CHALCOHALIDES FOR OPTOELECTRONIC LIGHT EMITTING DIODES

(71) Applicant: Northwestern University, Evanston, IL (US)

(72) Inventors: Mercouri G. Kanatzidis, Wilmette, IL (US); Craig Cameron Laing, Chicago, IL (US)

(21) Appl. No.: 18/994,354

(22) PCT Filed: Jul. 27, 2023
(86) PCT No.: PCT/US2023/028799

§ 371 Date: Jan. 14, 2025

Related U.S. Application Data
(60) Provisional application No. 63/369,681, filed on Jul. 28, 2022.

(51) Int. Cl. H10H 20/823; H10H 20/01

(52) U.S. Cl. CPC H10H 20/823; H10H 20/012

(57) ABSTRACT

Mixed anion rhenium chalcohalides, films of the mixed anion chalcohalides, and light-emitting diodes incorporating the mixed anion rhenium chalcohalides as active materials are provided. The mixed anion rhenium chalcohalides have the formula A₆Rₑ₆Q₈X₈, where A is an alkali metal atom, Q is a chalcogen element, and X is halogen atom. The mixed anion rhenium chalcohalides are characterized by [Rₑ₆Q₈X₆]⁴⁻ clusters, A⁺ cations, and X⁻ anions.

### CROSS-REFERENCE TO RELATED APPLICATIONS

The present application claims priority to U.S. provisional patent application No. 63/369,681 that was filed Jul. 28, 2022, the entire contents of which are incorporated herein by reference.

### REFERENCE TO GOVERNMENT RIGHTS

This invention was made with government support under DMR 1720139 awarded by the National Science Foundation. The government has certain rights in the invention.

### BACKGROUND

Materials discovery of novel optically active materials is critical for the future development of improved optoelectronic devices such as solar cells and light emitting diodes (LED). A substantial amount of recent work has investigated both old and new members of the hybrid perovskite family of materials for these applications due to their promising optoelectronic properties such as their strong photoluminescence (PL) and their solution processability enabling cheap and simple preparation of films that can be incorporated into optoelectronic devices. Rhenium chalcohalides are another family of optically active materials based on a hexanuclear rhenium (III) clusters that exhibit broad photoluminescence in the red to near IR region. (Gray, T. G. et al., Inorganic Chemistry 1999, 38 (26), 5932-5933; Gray, T. G. et al., Journal of the American Chemical Society 2003, 125 (16), 4755-4770; Kitamura, N. et al., Inorganic Chemistry 2005, 44 (18), 6308-6313; and Laing, C. C. et a., Chemistry of Materials 2021, 33 (14), 5780-5789.)

Research on this family of materials began with the initial discovery of Re₆Se₄Cl₁₀ and Re₆Q₄Br₁₀ (Q=Se, Te). (Opalovskii, A. A. et al., Russ. J Inorg. Chem. 1971, 16, 790; Opalovskii, A. A. et al., Russ. J Inorg. Chem. 1971, 16, 1685.) The discovery of the first soluble rhenium chalcohalide, KRe₆Se₅Cl₉ along with the later discovery of soluble phases such as Cs₅Re₆S₈Cl₇ that contain isolated [Re₆S₈X₆]⁴⁻ (X=Cl, Br, I) clusters bridged the gap from high temperature solid state chemistry to solution phase chemistry for these clusters. (Batail, P. et al., C. R. Acad. Sci. Ser. 2 1987, 304, 1111-1116; Long, J. R. et al., Angewandte Chemie International Edition in English 1995, 34 (2), 226-229; Long, J. R. et al., Journal of the American Chemical Society 1996, 118 (19), 4603-4616.) Additional solution phase work has investigated linking of clusters, ligand exchange reactions, the construction of larger molecules such as dendrimers and polymers, as well as the formation of extended frameworks and complex materials utilizing these clusters. Various members of this family of rhenium clusters including hybrid organic-cluster derivative materials have been studied as porous frameworks for catalysis, magnetic materials, therapeutic antitumoral agents, or functional two-dimensional (2D) semiconductors. The chemistry and properties of rhenium chalcohalides has been discussed at length by Gabriel et. al. (Gabriel, J.-C. et al., Chemical Reviews 2001, 101 (7), 2037-2066.)

The solubility of these rhenium chalcohalide clusters ultimately is the result of the control of the structure, bonding, and dimensionality of these materials. The three-dimensional (3D) parent structure for rhenium chalcohalides is the Re₆S₈Cl₂ structure type which is also adopted by Re₆Q₈X₂ (Q=S, Se; X=Br, I). The cluster core present in all members of this family of materials is comprised of 6 rhenium atoms that form the vertices of an octahedra and 8 atoms bonding to one of the faces of the octahedra. In the 3D Re₆S₈Cl₂ structure type, cluster cores are bound to each other through one of two types of covalent bonding. The first is a bridging halide bond (Re—X—Re) and the second is a pair of inter-cluster Re-Q bonds. Notably, Re₆Se₈Cl₂ adopts a 2D layered structure with adjacent clusters covalently bound exclusively through a pair of inter-cluster Re-Q bonds with Cl atoms instead terminating the layers in one direction. (Leduc, L. et al., Acta Crystallographica Section C 1983, 39 (11), 1503-1506.) These inter-cluster bonds can then be broken in a stepwise controlled manner through the controlled addition of alkali metal halide salt. Considering the Cs/Re/S/Br system as an example, it is possible to obtain the 3D Re₆S₈Br₂, the 2D Cs₄Re₆S₈Br₃, one dimensional (1D) Cs₂Re₆S₈Br₄, and the zero-dimensional (0D) salt Cs₄Re₆S₈Br₆. (Fischer, C. et al., Journal of Alloys and Compounds 1992, 178 (1), 305-314; Pilet, G. et al., Zeitschriftfur Kristallographie—New Crystal Structures 2002, 217 (JG), 11-12; Pilet, G. et al., Solid State Sciences 2004, 6 (1), 109-116.)

### BRIEF DESCRIPTION OF THE DRAWINGS

Illustrative embodiments of the invention will hereafter be described with reference to the accompanying drawings, wherein like numerals denote like elements.

FIGS. 1A-1B show crystal structures of (FIG. 1A) Rb₆Re₆S₈I₈ and (FIG. 1B) an isolated [Re₆S₈I₆]⁴⁻ cluster.

FIG. 2A shows diffuse reflectance of Rb₆Re₆S₈I₈ with an absorption edge of 2.06(5) eV. FIG. 2B shows work function of Rb₆Re₆S₈I₈ with value of 5.51(3) eV. FIG. 2C shows normalized PL at both 298 K and 77 K. The PL maximum shifts from 1.50 eV (827 nm) to 1.45 eV (855 nm) and the maximum emission energy shifts from 2.12 eV (584 nm) to 1.88 eV (659 nm). FIG. 2D shows a logarithmic scale plot of the PL lifetime at both 298 K of 77 s and 77 K of 99 μs.

FIG. 3A shows powder X-ray diffraction (PXRD) of a Rb₆Re₆S₈I₈ film indicating phase purity. FIG. 3B shows PL from a Rb₆Re₆S₈I₈ film showing retention of the PL emission range when cast as a film.

FIGS. 4A-4C show (FIG. 4A) LED device architecture, (FIG. 4B) a band alignment diagram and (FIG. 4C) emission spectra of an LED.

FIG. 5 shows energy-dispersive X-ray spectroscopy (EDS) spectra of a mixed anion rhenium chalcohalide having the formula Rb₆Re₆S₈I₈ crystal which had an experimentally determined atomic ratio of Rb_{6.10}Re_{6.00}S_{8.14}I_{7.29}.

FIG. 6 shows electronic band structure and partial density of states (PDOS) of Rb₆Re₆S₈I₈ calculated with Perdew-Burke-Ernzerhof (PBE) functional.

FIG. 7 shows phonon dispersion of Rb₆Re₆S₈I₈ calculated with PBE functional. Note the longitudinal optical (LO) and transverse optical (TO) splitting is not included.

FIG. 8 shows Raman spectroscopy of a Rb₆Re₆S₈I₈ single crystal. To understand the vibrations in Rb₆Re₆S₈I₈, the phonon modes were calculated. Since the primitive cell of Rb₆Re₆S₈I₈ has 28 atoms, there are a total of 84 phonon modes. The mode decomposition at the F-point is 3A_{1g}⊕3Eg⊕3T_{1g}⊕5T_{2g}⊕2A₂ᵤ⊕2Eᵤ⊕10T₁ᵤ⊕5T₂ᵤ.

FIG. 9 shows photoluminescence excitation (PLE) of Rb₆Re₆S₈I₈ dissolved in water.

FIG. 10 shows Grazing-Incident Wide-Angle Scattering (GIWAXS) analysis of a film of Rb₆Re₆S₈I₈ on a glass substrate. Integrations of the (111) and (002) rings over the angular coordinate χ are shown. Each graph shows an increase in intensity as χ approaches 0°, though the geometry of GIWAXS measurements prevents analysis near 0°. This indicates that there are two preferred orientations present in the film: one with the (111) plane oriented parallel to the substrate, indicated by the high intensity near 0° for the (111) ring; and one with the (002) plane parallel to the substrate, indicated by the high intensity near 0° for the (002) ring. The large peak at χ=550 for the (002) ring is from the (111)-oriented grains, in which the (002) peak is at a 55° angle from the (111) peak. The small peak at χ=70° for the (111) peak is from other (111) peaks within the same structure.

FIGS. 11A-11B show profilometry measurements of a Rb₆Re₆S₈I₈ film. FIG. 11A shows a film prepared in air with an average height of 152.7 nm and a roughness of 15.0 nm. FIG. 11B shows a film prepared in a nitrogen glovebox with an average height of 59.5 nm and a roughness of 16.7 nm. The few hundred nm spike in both are either islands in the respective films or artifacts.

FIG. 12 shows logarithmic scale lifetime of a film of Rb₆Re₆S₈I₈ on a glass substrate. The lifetime was fit to a two-component exponential decay. The first component lifetime is 8.75 μs and the second is 30.4 μs for an average PL lifetime of a Rb₆Re₆S₈I₈ film 22.5 μs.

FIG. 13A shows characterization of a Rb₆Re₆S₈I₈ film cast in a nitrogen glove box using PXRD showing a broad initial feature that matches with the first two reflections of Rb₆Re₆S₈I₈. The increased peak broadness compared to the other film is likely the result of both less material and less crystallinity compared to the films cast in air. FIG. 13B shows PL showing similar emission range that does extend slightly less on the high energy side than the films cast in air. The jaggedness of the PL spectra is due to instrument artifacts.

### SUMMARY

Photoluminescent mixed anion rhenium chalcohalides, methods of making the mixed anion rhenium chalcohalides films of the mixed anion chalcohalides, and light-emitting diodes incorporating the mixed anion rhenium chalcohalides as active materials are provided. Also provided are methods of making the mixed anion rhenium chalcohalides and thin films thereof.

One embodiment of mixed anion rhenium chalcohalide has the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions.

One embodiment of a supported mixed anion rhenium chalcohalide film includes: a substrate having a surface; and a film of a mixed anion rhenium chalcohalide on the surface of the substrate, wherein the mixed anion rhenium chalcohalide having the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions.

One embodiment of a light emitting diode includes: an electron transport layer; a hole transport layer; an active layer comprising the mixed anion rhenium chalcohalide disposed at least partially between the electron transport layer and the hole transport layer, wherein the mixed anion rhenium chalcohalide has the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions; a first electrically conductive contact in electrical communication with the electron transport layer; and a second electrically conductive contact in electrical communication with the hole transport layer.

One embodiment of method of forming a mixed anion rhenium chalcohalide includes the steps of: forming a mixture of two or more chalcohalide precursors, the mixture comprising at least one precursor comprising rhenium, at least one precursor comprising an alkali metal atom, at least one precursor comprising sulfur, selenium, or tellurium, and at least one precursor comprising a halogen atom; melting the chalcohalide precursors; and reacting the chalcogenide precursors in the melt under vacuum to form the mixed anion rhenium chalcohalide, wherein the mixed anion rhenium chalcohalide has the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions.

One embodiment of a method of forming a mixed anion rhenium chalcohalide film includes the steps of: forming a solution comprising one or more of the mixed anion rhenium chalcohalides in a solvent; forming a coating of the solution on a surface of a substrate; and drying the coating to form a solid film of the one or more of the mixed anion rhenium chalcohalides on the surface of the substrate, wherein the mixed anion rhenium chalcohalide has the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions.

### DETAILED DESCRIPTION

Photoluminescent mixed anion rhenium chalcohalides, films of the mixed anion chalcohalides, and light-emitting diodes incorporating the mixed anion rhenium chalcohalides as active materials are provided. Also provided are methods of making the mixed anion rhenium chalcohalides and thin films thereof.

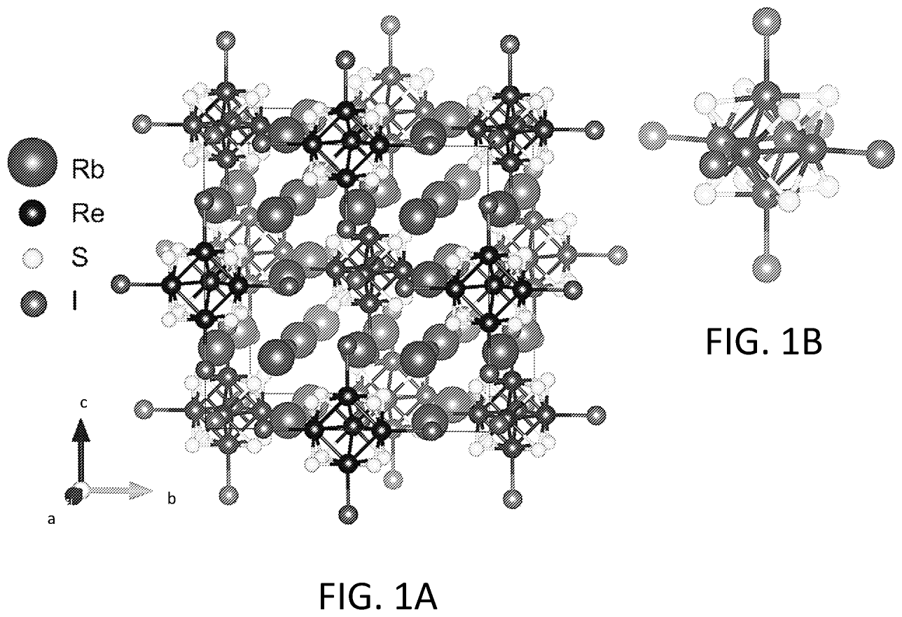

The mixed anion rhenium chalcohalides have the formula A₆Re₆Q₈X₈, where A is an alkali metal atom, such as lithium (Li), sodium (Na), potassium (K), rubidium (Rb) and/or cesium (Cs), Q is a chalcogen element selected from selenium (Se), sulfur (S), and/or tellurium (Te), and X is a halogen atom, such as fluorine (F), chlorine (Cl), bromine (Br), and/or iodine (I). The mixed anion rhenium chalcohalides are characterized by [Re₆Q₈X₆]⁴⁻ clusters, A⁺ cations, and X⁻ anions. This structure is illustrated in FIGS. 1A and 1B using Rb₆Re₆S₈I₈ as an illustrative example of a mixed anion rhenium chalcohalide. The [Re₆Q₈X₆]⁴⁻ cluster is illustrated in FIG. 1B.

The mixed anion rhenium chalcohalides are indirect semiconductors which exhibit photoluminescence and, as such, have applications in light-emitting optoelectronic devices, such as light-emitting diodes (LEDs).

Without intending to limit the inventions described herein to any particular theory, the origin of the photoluminescence for [Re₆Q₈X₆]⁴⁻ clusters in A₆Re₆Q₈X₈ can be explained by four excited triplet states in the cluster. These triplet states can result in spin forbidden relaxations giving rise to long photoluminescence lifetimes. Moreover, the solid-state arrangement of the clusters in all-inorganic A₆Re₆Q₈X₈ chalcohalides may mitigate any interactions causing carrier relaxation to occur via a nonradiative pathway.

The inorganic mixed anion rhenium chalcohalides can be used as active materials in optoelectronic devices. The basic components of an optoelectronic device include a first electrically conductive contact; a second electrically conductive contact; and an active layer comprising or consisting of one or more inorganic mixed anion rhenium chalcohalides. The first and second electrically conductive contacts are configured to apply an electric field across the photoactive material and/or to pass an electric current through the photoactive material.

Light-emitting diodes (LEDs) are examples of optoelectronic devices into which the mixed anion rhenium chalcohalides can be used as active materials. In addition to the components described above, LEDs include an electron transport layer and a hole transport layer, between which at least part of the active layer is disposed. Other layers that may optionally be included in an LED include a hole injection layer disposed between the hole transport layer and an electrically conductive contact and an electron injection layer disposed between the electron transport layer and the other electrically conductive contact.

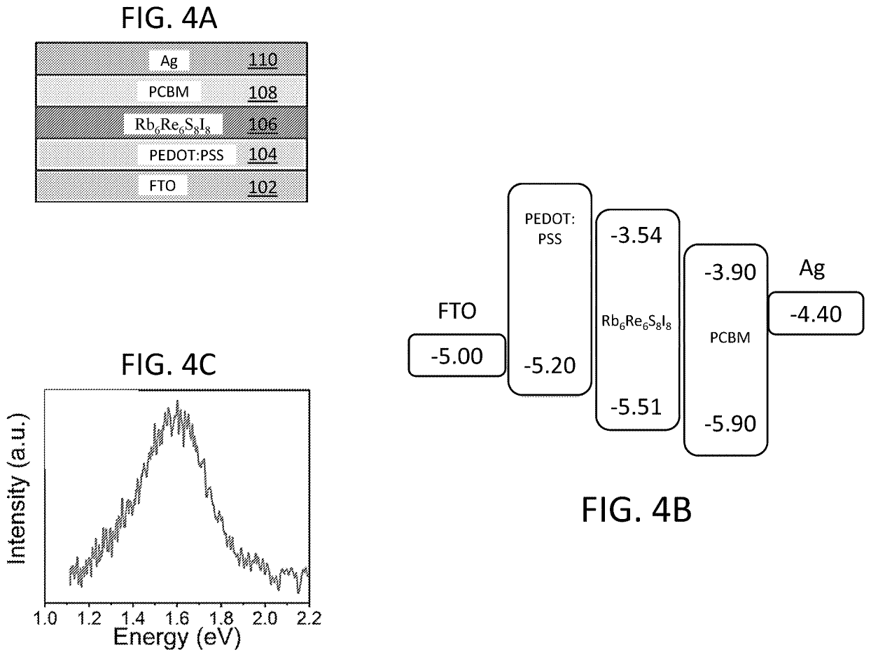

A schematic diagram showing a cross-sectional view of an LED is shown in FIG. 4A. The LED includes a thin film stack comprising from bottom to top: a first electrically conductive contact 102, a hole transport layer (HTL) 104, an active layer 106 comprising at least one photoluminescent mixed anion rhenium chalcogenide of a type described herein, an electron transport layer (ETL) 108 and a second electrically conductive contact 110. One or both of the electrically conductive contacts is transparent at the operational wavelengths of the LED. The specific materials used for the LED of FIG. 4A are for illustrative purposes only. Other materials can be used.

The mixed anion rhenium chalcogenides can be synthesized by combining two or more starting chalcohalide precursors, at least one of which comprises rhenium, in a reaction vessel and reacting the chalcohalide precursors under vacuum at a temperature greater than the melting points of the precursors to form the mixed anion rhenium chalcohalide. The precursors may be solid precursors, such as powders, or gaseous precursors, such as dihalides. Conducting the synthesis reaction under vacuum condenses any gaseous precursors and prevents unwanted side reactions, such as oxidation.

In the melt used for the synthesis of the mixed anion rhenium chalcohalides the precursors are present in appropriate stoichiometric ratios to form the desired compounds. Once formed, the inorganic compounds can be solidified and used as raw materials for forming films of the mixed anion rhenium chalcohalide films or for growth of high-quality crystals. The chalcohalide precursors contain all of the elements of the mixed anion rhenium chalcohalides and can comprise elemental precursors, binary precursors, ternary precursors, higher order precursors, and combinations thereof. The composition of the precursors will depend on the mixed anion rhenium chalcohalide being synthesized. Examples of suitable chalcohalide precursors include: elemental metals, such as rhenium metal, lithium metal, sodium metal, potassium metal, rubidium metal, and/or cesium metal; metal halides, such as lithium halides, sodium halides, potassium halides, rubidium halides, and/or cesium halides, wherein halides include fluoride compounds, chloride compounds, bromide compounds, and iodide compounds; metal chalcogenides, such as rhenium disulfide, rhenium diselenide, and/or rhenium ditelluride; and/or dihalides, such as F₂, Cl₂, Br₂ and/or I₂.

The mixed anion rhenium chalcohalides are soluble in various solvents, including water and other polar solvents, such as N,N-dimethylformamide (DMF), N-methylformamide (NMF), N-methyl-2-purrolidone, and dimethylacetamide, dimethyl sulfoxide. The mixed anion rhenium chalcohalides can be considered sufficiently soluble in a given solvent if they have a solubility of at least about 0.2 mg/μl at room temperature (23° C.) in that solvent. As used herein the term solvent includes solvent mixtures.

The solubility of the mixed anion rhenium chalcohalides enables solution processing the chalcohalides into thin solid films using various solution-based film-forming techniques, such as spin coating, drop casting, and doctor blading. The general process of film formation includes the steps of forming a solution comprising one or more of the mixed anion rhenium chalcohalides described herein in a solvent, forming a coating of the solution on a surface of a substrate, and drying the coating to form a solid film of the one or more of the mixed anion rhenium chalcohalides on the surface of the substrate. The films can be very thin, including films having a thickness of 1 μm or less. This includes films having a thickness of 500 nm or less and films having a thickness of 200 nm or less. By way of illustration solid films of the mixed anion rhenium chalcohalides having thicknesses in the range from 10 nm to 150 nm can be formed.

### Example

This Example illustrates the structural, thermal, optical, and electronic properties of Rb₆Re₆S₈I₈, a new fully inorganic rhenium chalcohalide, and demonstrate its use as the first rhenium chalcohalide in an LED. Rb₆Re₆S₈I₈ is used as an illustrative example. It should be understood that the same procedures can be used to make other members of the mixed anion rhenium chalcohalides by substituting the precursors used in this example with other precursors containing the desired metal, chalcogen, and halogen elements.

The Rb₆Re₆S₈I₈ crystallizes in the cubic space group Fm3̅m with isolated [Re₆S₈I₆]⁴⁻ clusters, Rb⁺ and I⁻ ions. The compound exhibits broad PL emission that spans from 1.01 eV to 2.12 eV (1230 nm to 585 nm) and has the longest reported room temperature rhenium chalcohalide cluster PL lifetime of 77 s. Additionally it also has the highest reported Re₆ cluster PL quantum yield (PLQY) of 42.7% at room temperature. Rb₆Re₆S₈I₈ can be solution processed into thin films by a simple one step spin coating from a DMF solution followed by annealing at 150° C. Thin films were then used as the active layer in a LED device demonstrating a rhenium chalcohalide cluster-based LED for the first time.

### Experimental Methods

### Reagents

Re (99.997%, ProChem Inc., Alpharetta, GA), S (99.99%, 5N Plus Inc., Saint-Laurent, Quebec, Canada). and 12 (99.8%, Sigma-Aldrich, St. Louis, MO) were used as purchased without additional purification. RbI (99.9%, Alfa Aesar, Ward Hill, MA) was melted with a methane and oxygen torch under dynamic vacuum and then allowed to cool and recrystallize before use.

Rb₆Re₆S₈I₈ Synthesis

Rb₆Re₆S₈I₈ was synthesized from RbI (0.9600 g, 4.520 mmol), Re (0.2525 g, 1.356 mmol), and S (0.0580 g, 1.808 mmol), which were mechanically mixed in air in an agate mortar and pestle and charged to a 15 mm outer diameter and 12 mm inner diameter lined with Al foil to prevent powder from sticking to the walls. I₂ (0.2295 g, 0.9014 mmol) was then added on top of the mixture and the Al foil was discarded. This resulted in a 20:6:8:4 molar ratio of RbI:Re:S:I₂ in the tube. The tube was then evacuated until a pressure of 1.0×10⁻² mbar was reached and then cooled with liquid nitrogen for thirty seconds. This condensed the I₂ and prevented it from escaping while having provided time for water vapor and oxygen to have been removed from the tube without condensing in the tube. The tube was then flame-sealed at 3.0×10⁻³ mbar with an internal length of 10 cm. To prevent vapor transport of ReS₂, the sealed tube was positioned in a one zone tube furnace such that the reagents were adjacent to the thermocouple near the cooler outer edge of the furnace while the other end of the tube was in the hotter center of the furnace. To prevent over pressurizing the tube, the iodine pressure was estimated assuming all of the iodine was a gas at the maximum temperature with 36% dissociation for a maximum calculated pressure of 9.5 atm. The furnace was heated to 800° C. in 9 hours, held there for 36 hours, cooled to 625° C. at a rate of 2° C./hour, and then the furnace was turned off and allowed to cool to room temperature. Orange crystals of Rb₆Re₆S₈I₈ suitable for characterization were mechanically separated from the rest of the product.

Rb₆Re₆S₈I₈ Film Fabrication

Films of Rb₆Re₆S₈I₈ were made both in air and in a nitrogen glovebox by spin coating solutions of Rb₆Re₆S₈I₈ onto a cleaned glass substrate. The glass substrates were cleaned by sequentially submerging and sonicating the substrates for five minutes each in aqueous detergent, deionized water, acetone and then ethanol which was followed by a five-minute UV-ozone treatment. The Rb₆Re₆S₈I₈ solutions were prepared at a concentration of 0.2 mg/μL using recrystallized phase pure Rb₆Re₆S₈I₈ and anhydrous DMF in a glovebox. The solution was allowed to sit at ambient temperature for an hour until no visible solid remained, at which point the solution was syringe filtered with a polytetrafluoroethylene (PTFE) 0.2 μm disposable filter. Then 50 μL of Rb₆Re₆S₈I₈ solution was deposited on the cleaned glass substrate and spread to cover the entire substrate. The spin coating was carried out at 4000 rpm for 30 seconds. This was followed by 30 minutes of annealing at 150° C. on a hot plate. The films had a yellow/orange tint.

### Light Emitting Diode (LED) Fabrication

Fluorine-doped tin oxide (FTO) substrates were cleaned by sequentially submerging and sonicating the substrates for five minutes each in aqueous detergent, deionized water, acetone and then ethanol which was followed by a twenty-minute UV-treatment. PEDOT:PSS solution (50 L) was used as the hole transport layer by spin coating at 6000 rpm for 30 seconds followed by a 30-minute annealing at 150° C. in air. At this point the substrate was transferred to a glovebox for the rest of the device fabrication process. 50 μL of Rb₆Re₆S₈I₈ in anhydrous DMF solution (0.252 mg/μL concentration prepared in an otherwise identical manner as described in the film fabrication section) was spin coated at 4000 rpm for 30 seconds followed by 150° C. annealing step for 30 minutes. A layer of [6,6]-phenyl-C61-butyric acid methyl ester (PCBM) as the electron transport layer (30 μL of a 0.02 mg/μL solution in chlorobenzene) was spin coated at 1000 rpm for seconds without an anneal step. This was then followed by the thermal deposition in a metal deposition chamber of silver to make a 100 nm thick layer. The area of the LEDs constructed had areas of either 0.09 cm² and 0.39 cm².

### Single Crystal X-Ray Diffraction

Intensity data was collected from a suitable irregularly shaped crystal of Rb₆Re₆S₈I₈ mounted on a glass fiber with super glue and diffracted using an IPDS 2 single crystal X-ray diffractometer at 293 K operating at 50 kV and 40 mA with Mo Kα radiation (λ=0.71073 Å) sealed X-ray source with X-ray fiber optics and an image plate detector. Data collection, data reduction, and a numerical absorption correction were performed using STOE X-Area version 1.90 software package, STOE X-Red version 1.65.2, and STOE X-Shape version 2.21 followed by scaling and outlier rejection with STOE LANA version 1.83.8. (STOE & Cie GmbH (2020), X-area version 1.90, X-red version 1.65.2, X-Shape version 2.21, software package for collecting single-crystal data on STOE diffractometers, for image processing, scaling reflection intensities and for outlier rejection; Darmstadt, Germany; Koziskova, J. et al., Acta Chimica Slovaca 2016, 9 (2), 136-140.) The structure solution was performed using the ShelXT intrinsic phasing solution method and was refined with ShelXL full matrix least squares minimization of F² method. (Sheldrick, G., Acta Crystallographica Section A 2015, 71 (1), 3-8; Sheldrick, G., Acta Crystallographica Section C 2015, 71 (1), 3-8.) Olex2 version 1.5 was used as the graphical interface. (Dolomanov, O. V. et al., Journal of Applied Crystallography 2009, 42 (2), 339-341.) Select crystallographic information can be found in Table 1 and complete crystallographic information can be found in Tables 2 to 6.

TABLE 1
Rb₆Re₆S₈I₈ crystallographic data.

| Formula weight | 5803.40 | |
|---|---|---|
| Temperature | 293 | K |
| Wavelength | 0.71073 | Å |
| Crystal system | Cubic | |
| Space group | Fm3̅m | |
| Unit cell | a = b = c = 15.5443(18) Å | |
| dimensions | α = β = γ = 90° | |
| Volume | 3755.9(13) | Å³ |
| Density (calculated) | 5.132 | g/cm³ |
| Independent | 468 | |
| reflections | [Rᵢₙₜ = 0.0170] | |
| Completeness to θ = | 99.1% | |
| 25.242° | | |
| Goodness-of-fit | 1.267 | |
| Final R indices [I > | R_{obs} = 0.0182 | |
| 2σ(I)] | wR_{obs} = 0.0438 | |
| R indices [all data] | Rₐₗₗ = 0.0192 | |
| | wRₐₗₗ = 0.0439 | |
| Extinction | 0.000271(12) | |
| coefficient | | |
| Largest diff. peak | 1.267 and −1.070 e · Å⁻³ | |
| and hole | | |

R = Σ∥Fₒ| − |F_{c}∥/Σ|Fₒ|, wR = {Σ[w(|Fₒ|² − [F_{c}]²)²]/Σ[w(|Fₒ|⁴)]}^{1/2} and w = 1/[σ²(Fo²) + (0.0144P)² + 75.2596P] where P = (Fo² + 2Fc²)/3

TABLE 2
Crystal data and structure refinement for Rb₆Re₆S₈I₈ at 293(2) K.

| Empirical formula | Rb₃Re₃S₄I₄ | |
|---|---|---|
| Formula weight | 5803.40 | |
| Temperature | 293 | K |
| Wavelength | 0.71073 | Å |
| Crystal system | Cubic | |
| Space group | Fm3̅m | |
| Unit cell dimensions | a = b = c = 15.5443(18) Å | |
| | α = β = γ = 90° | |
| Volume | 3755.9(13) | Å³ |
| Z | 2 | |
| Density (calculated) | 5.132 | g/cm³ |
| Absorption coefficient | 34.005 | mm⁻¹ |

| | |
|---|---|
| F(000) | 4896 |
| Crystal size | 0.12 × 0.10 × |
| | 0.10 mm³ |
| θ range for data collection | 2.621 to 34.921° |
| Index ranges | −24 <= h <= 24 |
| | −23 <= k <= 24 |
| | −23 <= l <= 24 |
| Reflections collected | 9301 |
| Independent reflections | 468 [Rᵢₙₜ = 0.0170] |
| Completeness to θ = 25.242° | 99.1% |
| Refinement method | Full-matrix least-squares |
| | on F² |
| Data/restraints/parameters | 468/0/15 |
| Goodness-of-fit | 1.267 |
| Final R indices [I > 2σ(I)] | R_{obs} = 0.0182, wR_{obs} = 0.0438 |
| R indices [all data] | Rₐₗₗ = 0.0192, wRₐₗₗ = 0.0439 |
| Extinction coefficient | 0.000271(12) |
| Largest diff. peak and hole | 1.267 and −1.070 e · Å⁻³ |

R = Σ∥Fₒ| − |F_{c}∥/Σ|Fₒ|, wR = {Σ[w(|Fₒ|² − [F_{c}]²)²]/Σ[w(|Fₒ|⁴)]}^{1/2} and w = 1/[σ²(Fo²) + (0.0144P)² + 75.2596P] where P = (Fo² + 2Fc²)/3

TABLE 3
Atomic coordinates (×10⁴) and equivalent isotropic
displacement parameters (Å² × 10³) for Rb₆Re₆S₈I₈
at 293(2) K with estimated standard deviations in parentheses.

| Label | x | y | z | Occupancy | U_{eq}* |
|---|---|---|---|---|---|
| Rb(1) | 7500 | 5000 | 2500 | 1 | 47(1) |
| Re(1) | 6180(1) | 5000 | 5000 | 1 | 17(1) |
| S(1) | 6092(1) | 6092(1) | 6092(1) | 1 | 23(1) |
| I(1) | 7963(1) | 5000 | 5000 | 1 | 37(1) |
| I(2) | 7500 | 2500 | 2500 | 1 | 35(1) |

*U_{eq} is defined as one third of the trace of the orthogonalized Uᵢⱼ tensor.

TABLE 4
Anisotropic displacement parameters (Å² × 10³) for Rb₆Re₆S₈I₈
at 293(2) K with estimated standard deviations in parentheses.

| Label | U₁₁ | U₂₂ | U₃₃ | U₁₂ | U₁₃ | U₂₃ |
|---|---|---|---|---|---|---|
| Rb(1) | 47(1) | 48(1) | 47(1) | 0 | 20(1) | 0 |
| Re(1) | 14(1) | 18(1) | 18(1) | 0 | 0 | 0 |
| S(1) | 23(1) | 23(1) | 23(1) | −4(1) | −4(1) | −4(1) |
| I(1) | 17(1) | 47(1) | 47(1) | 0 | 0 | 0 |
| I(2) | 35(1) | 35(1) | 35(1) | 0 | 0 | 0 |

The anisotropic displacement factor exponent takes the form: −2π²[h²a*²U₁₁ + . . . + 2hka*b*U₁₂].

TABLE 5
Bond lengths [Å] for Rb₆Re₆S₈I₈ at 293(2) K with
estimated standard deviations in parentheses.

| Label | Distances |
|---|---|
| Rb(1)-S(1)#1 | 3.5302(9) |
| Rb(1)-I(1) | 3.9522(5) |
| Rb(1)-I(2) | 3.8861(5) |
| Re(1)-Re(1)#5 | 2.5950(5) |
| Re(1)-S(1) | 2.4043(15) |
| Re(1)-I(1) | 2.7709(8) |

Symmetry transformations used to generate equivalent atoms:
(1) −x + 3/2, y, z − 1/2 (2) x, y, −z + 1 (3) x, −y + 1, −z + 1 (4) −x + 3/2, −y + 1, z − 1/2 (5) −y + 1, −z + 1, −x + 1 (6) −x + 3/2, −y + 1, −z + 1/2 (7) y + 1/2, z, x − 1/2 (8) −z + 1, −x + 1, −y + 1 (9) y, z, x (10) z, x, y (11) x, −y + 1, z (12) −x + 3/2, −y + 1, z + 1/2 (13) −y + 1, z + 1/2, −x + 3/2 (14) z + 1/2, x − 1/2, y (15) z + 1/2, −x + 3/2, −y + 1 (16) −y + 1, z, −x + 1 (17) −x + 3/2, −y + 1/2, z (18) z + 1/2, −x + 1, −y + 1/2

TABLE 6
Bond angles [°] for Rb₆Re₆S₈I₈ at 293(2) K with
estimated standard deviations in parentheses.

| Label | Angles |
|---|---|
| S(1)#1-Rb(1)-S(1)#3 | 180.00(3) |
| S(1)#3-Rb(1)-S(1)#4 | 122.52(5) |
| S(1)#1-Rb(1)-S(1)#4 | 57.48(5) |
| S(1)#1-Rb(1)-I(1) | 119.783(11) |
| S(1)#2-Rb(1)-I(1) | 60.217(11) |
| S(1)#3-Rb(1)-I(2) | 61.26(3) |
| S(1)#1-Rb(1)-I(2) | 118.74(3) |
| I(1)-Rb(1)-I(1)#5 | 110.989(18) |
| I(1)-Rb(1)-I(1)#6 | 180.0 |
| I(1)-Rb(1)-I(1)#7 | 69.011(18) |
| I(2)-Rb(1)-I(1) | 90.0 |
| I(2)#6-Rb(1)-I(2) | 180.0 |
| Re(1)#8-Re(1)-Re(1)#9 | 60.0 |
| Re(1)#5-Re(1)-Re(1)#9 | 90.0 |
| Re(1)#5-Re(1)-I(1) | 135.0 |
| S(1)-Re(1)-Re(1)#5 | 117.30(2) |
| S(1)-Re(1)-Re(1)#9 | 57.34(2) |
| S(1)-Re(1)-S(1)#3 | 173.43(6) |
| S(1)-Re(1)-S(1)#2 | 89.812(3) |
| S(1)-Re(1)-I(1) | 93.28(3) |
| Rb(1)#12-S(1)-Rb(1)#13 | 102.23(3) |
| Re(1)#10-S(1)-Rb(1)#12 | 154.55(5) |
| Re(1)-S(1)-Rb(1)#12 | 93.599(7) |
| Re(1)-S(1)-Rb(1)#13 | 154.55(5) |
| Re(1)#9-S(1)-Re(1) | 65.32(5) |
| Rb(1)#14-I(1)-Rb(1) | 88.099(3) |
| Rb(1)-I(1)-Rb(1)#12 | 159.011(18) |
| Re(1)-I(1)-Rb(1) | 79.506(9) |
| Rb(1)#16-I(2)-Rb(1) | 90.0 |
| Rb(1)-I(2)-Rb(1)#17 | 180.0 |

Symmetry transformations used to generate equivalent atoms:
(1) −x + 3/2, y, z − 1/2 (2) x, y, −z + 1 (3) x, −y + 1, −z + 1 (4) −x + 3/2, −y + 1, z − 1/2 (5) −y + 1, −z + 1, −x + 1 (6) −x + 3/2, −y + 1, −z + 1/2 (7) y + 1/2, z, x − 1/2 (8) −z + 1, −x + 1, −y + 1 (9) y, z, x (10) z, x, y (11) x, −y + 1, z (12) −x + 3/2, −y + 1, z + 1/2 (13) −y + 1, z + 1/2, −x + 3/2 (14) z + 1/2, x − 1/2, y (15) z + 1/2, −x + 3/2, −y + 1 (16) −y + 1, z, −x + 1 (17) −x + 3/2, −y + 1/2, z (18) z + 1/2, −x + 1, −y + 1/2

### UV-Vis Diffuse Reflectance Measurements

Diffuse-reflectance measurements were conducted at room temperature from 200 to 2000 nm on a powdered Rb₆Re₆S₈I₈ sample using a Shimadzu UV-3600 PC double-beam, double-monochromator spectrophotometer, and BaSO₄ was used as a non-absorbing reference. The generated reflectance data were transformed to absorbance via the Kubelka-Munk equation α/S=(1−R)²/2R, where R is the reflectance, a is the absorption coefficient and S is the scattering coefficient. (Kortum, G. et al., Angewandte Chemie International Edition in English 1963, 2 (7), 333-341.) The band gap was estimated by extrapolation of the linear region.

### Electronic Band Structure, Phonon Structure and Raman Stretch Calculations

All density functional theory (DFT) calculations were carried out using the Vienna ab initio simulation package (VASP) along with the projector augmented wave (PAW) method. (Hohenberg, P. et al., Physical Review 1964,136 (3B), B864-B871; Kohn, W.; Sham, L. J., Physical Review 1965,140 (4A), A1133-A1138; Kresse, G. et al., Computational Materials Science 1996, 6 (1), 15-50; Kresse, G. et al., Physical Review B 1996, 54 (16), 11169-11186; Blöchl, P. E., Physical Review B 1994, 50 (24), 17953-17979.) The Perdew-Burke-Ernzerhof (PBE) version of the generalized gradient approximation (GGA) to the exchange-correlation functional was employed. (Perdew, J. P. et al., Physical Review Letters 1996, 77(18), 3865-3868; Kresse, G. et al., Physical Review B 1999, 59 (3), 1758-1775.) The F-centered Monkhorst-Pack grid of 9×9×6 was used for the primitive cell Rb₆Re₆S₈I₈ (28 atoms). The plane wave basis set with cutoff energy of 520 eV was adopted. The structure was fully relaxed until the total energy converged to 10⁻⁷ eV and the force on each atom was less than 0.01 eV/Å. Phonon calculations were performed with the 112-atom conventional cell using the PHONOPY package. (Togo, A. et al., Scripta Materialia 2015, 108, 1-5.)

### Grazing-Incident Wide-Angle Scattering (GIWAXS)

GIWAXS measurements were performed at Beamline 8-ID-E of the Advanced Photon Source at Argonne National Laboratory. Samples prepared on glass substrates were exposed to an X-ray beam (λ=1.14 Å) at an incident angle of either 0.140 or 0.40° for 1 s, and the scattered light was collected by a Pilatus 1 M pixel array detector at 228 mm from the sample. The GIXSGUI program was used to plot images of the patterns and analyze the data. (Jiang, Z., Journal of Applied Crystallography 2015, 48 (3), 917-926.)

### Results and Discussion

### Synthesis and Thermal Characterization

Rb₆Re₆S₈I₈ crystals were grown using RbI salt flux with excess 12 from the reagents RbI:Re:S:I₂ in the stoichiometric ratio 20:6:8:4 heated in a sealed tube under vacuum to 800° C. As the reaction vessel heated up, the RbI melted and was likely allowing for some of the gaseous iodine to dissolve via I₂+I⁻→I₃⁻ which can then react with the Re and S to form the clusters and eventually crystallize into Rb₆Re₆S₈I₈. The synthetic parameters of note in preparing this material are the amount of iodine used and the temperature gradient of the reaction vessel experiences to avoid excess iodine pressure from exploding the reaction vessel and preventing iodine from performing chemical vapor transport (CVT) of ReS₂ across the tube away from the RbI preventing the reaction from progressing. The iodine pressure can be addressed by considering the amount of iodine used and the volume of the reaction vessel. CVT was suppressed by taking advantage of the natural temperature gradient in a tube furnace by placing the bottom of the reaction vessel containing the starting material at an outer end of the furnace while the other end was situated in the hot center of the tube furnace.

Bulk phase pure Rb₆Re₆S₈I₈ was also prepared with RbI as a limiting reagent with RbI:Re:ReS₂:I₂ in the stoichiometric ratio 4:2:4:4.5 heated in a sealed tube under vacuum to 850° C. for 4 days. The product was then ground up and sealed in a new tube with additional iodine and again heated to 850° C. for 4 days at which point no RbI reflection could be observed in the PXRD powder pattern. Additional reflections observed in the data are the result of an unidentified phase which is highly likely to be either a 2D RbRe₆S₈I₃ phase, a 1D Rb₂Re₆S₈I₄ phase or some other composition of the type xRbI+Re₆S₈I₂. This resulted in a mixture where the only soluble product was Rb₆Re₆S₈I₈. The product was then ground and homogenized and then allowed to dissolve in DMF. The concentrated solution was then syringe filtered and Rb₆Re₆S₈I₈ was recrystallized to obtain bulk pure material by heating the solution overnight at 110° C.

Differential thermal analysis (DTA) of a sample of Rb₆Re₆S₈I₈ sealed in a fused silica ampoule under vacuum was used to determine the melting point and facilitate the optimization of crystal growth of Rb₆Re₆S₈I₈. The sample was thermally cycled to 850° C. twice and reproducible thermal events were assigned as the melting point at 757° C. and the crystallization point at 745° C. Powder X-ray diffraction (PXRD) comparing the material pre-DTA to post-DTA indicated that Rb₆Re₆S₈I₈ was recovered as the primary phase with a small additional reflection corresponding to a small amount of ReS₂. Additionally, a trace amount of I₂ was observed at the top of the ampoule after the DTA and the previously orange crystals had darkened in color. This indicated that a small degree of decomposition occurred when Rb₆Re₆S₈I₈ was melted under vacuum. Based on these results, an optimized crystal growth process of Rb₆Re₆S₈I₈ was developed, by heating the reagents into the melt at 800° C. with excess iodine followed by slow cooling through the crystallization point of both Rb₆Re₆S₈I₈ at 745° C. and RbI at 647° C. at 1° C. per hour. This led to a phase separation of the excess RbI from the Rb₆Re₆S₈I₈ that was mechanically separated for the following optical property measurements.

### Crystal Structure

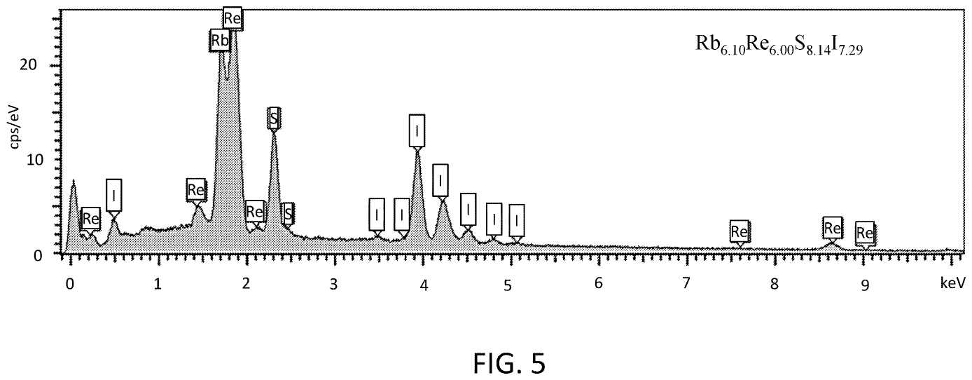

Rb₆Re₆S₈I₈ crystallizes in the cubic zero-dimensional (0D) Cs₆Re₆S₈I₈ structure type with the space group Fm3̅m containing Rb⁺, I⁻ and [Re₆S₈I₆]⁴⁻ ions as shown in FIGS. TA-TB. The composition was confirmed using energy dispersive spectroscopy (EDS) in a scanning electron microscope (SEM) as shown in FIG. 5. Rb₆Re₆S₈I₈ is the dimensionally reduced 0D rubidium derivative of the 3D parent compound Re₆S₈I₂. The 20 atom [Re₆S₈I₆]⁴⁻ cluster shown in FIG. 1B is comprised of a [Re₆S₈]²⁺ cluster core with 6 rhenium atoms in a 3+ oxidation state forming an octahedra. The Re—Re bond length is 2.5950(5) Å. Each sulfur atom then caps one of the faces of the octahedra in μ₃ interaction with three rhenium atoms that form each face of the octahedra with a Re—S bond length of 2.4043(15) Å. Each iodine atom forms a terminal Re—I bond to one of the rhenium atoms with a Re—I bond length of 2.7709(8) Å.

This 0D structure type can be understood as a derivative of the NaCl rock salt structure type. Taking the analogous RbI as the parent structure, every cluster core [Re₆S₈]²⁺ replaces one rubidium atom in addition to creating a vacancy at a second rubidium site to maintain charge balance. Additionally, the 6 terminal iodine atoms covalently bound to the cluster core move slightly off the typical iodide position towards these rubidium site vacancies due to the bulkier size of the cluster core compared with a Rb⁺ ion. For each [Re₆S₈I₆]⁴⁻ cluster there are four Rb⁺ cations to charge balance which together co-crystallizes with two additional RbI equivalents. These two additional RbI equivalents provides the additional Rb⁺ and I⁻ ions needed to occupy the remaining sites in the rock salt arrangement.

### Electronic and Optical Properties

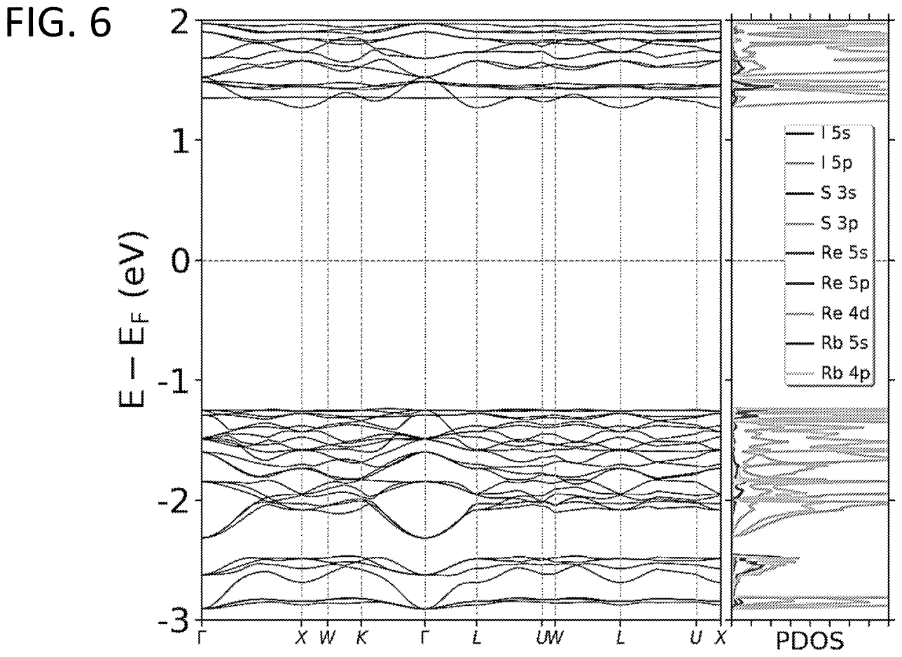

The electronic band structure and partial density of states (PDOS) of Rb₆Re₆S₈I₈ are shown in FIG. 6. Rb₆Re₆S₈I₈ is an indirect band gap semiconductor, where the conduction band minimum (CBM) occurs at X and L points and the valence band maximum (VBM) occurs in the Γ-K direction (Σ line). The top of valence band is very flat which is consistent with 0D ionic nature of the material while the bottom of the conduction band has a small degree of dispersion (~0.1 eV). The PDOS indicates that Re 4d provides most of the orbital contribution that comprises that band edges in the material along with some S 3p and Re 5p contributions to both band edges.

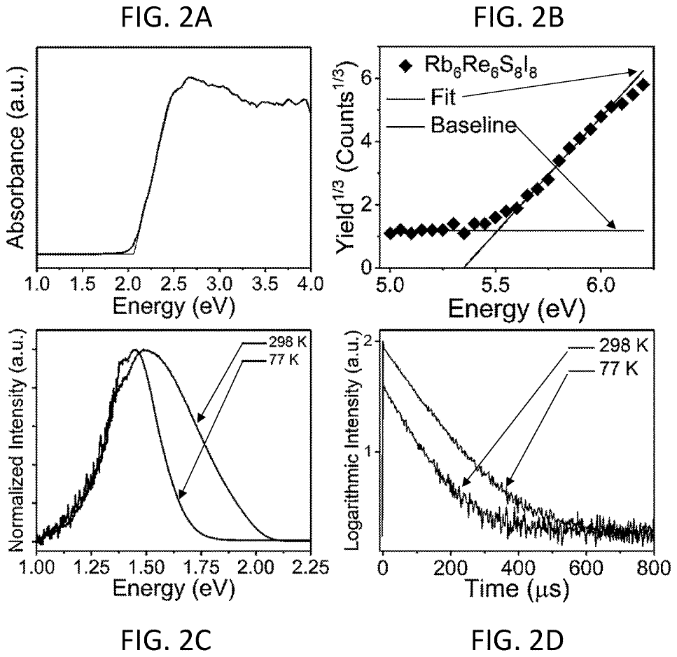

The optical properties shown in FIGS. 2A-2D were probed using UV-vis diffuse reflectance spectroscopy, photoemission yield spectroscopy in air measurements (PYSA) and photoluminescence measurements. (Harwell, J. R. et al., Physical Chemistry Chemical Physics 2016, 18 (29), 19738-19745; Yamashita, D.; Ishizaki, A., Applied Surface Science 2016, 363, 240-244.) The band gap shown in FIG. 2A was found to be 2.06(5) eV (602 nm). The work function shown in FIG. 2B which is equal to the energy of the valence band maximum (VBM) with respect to the energy of a free electron was found to be 5.51(3) eV. Considering the band gap in combination with the work function gives a conduction band minimum (CBM) of 3.45(6) eV with respect to the energy of a free electron. These values enable the selection of more optimal carrier transport materials when constructing an optoelectronic device.

To probe the emission properties of Rb₆Re₆S₈I₈ crystals grown from the high temperature reaction, the photoluminescence was measured at both room temperature and 77 K as shown in FIG. 2C. The room temperature emission ranges from 1.01 eV to 2.12 eV (1230 nm to 585 nm) with a peak maximum at 1.50 eV (827 nm), while the emission slightly narrows at 77 K emitting from 1.01 eV to 1.88 eV (1230 nm to 659 nm), with a slightly red shifted peak maximum to 1.45 eV (855 nm). The time-resolved photoluminescence (TRPL) of Rb₆Re₆S₈I₈ was measured at 293 K and 77 K where both temperatures fit well to a single exponential decay with very long lifetimes of 77 s at 293 K and slightly slower decay with a lifetime of 99 μs at 77 K, as shown in FIG. 2D. The room temperature photoluminescence quantum yield (PLQY) of crystals of Rb₆Re₆S₈I₈ taken from the high temperature synthesis is 42.7%. This value is slightly undercounting the amount of light emitted from the material due to instrumental limitations where photons with a wavelength above 950 nm (below 1.305 eV) that were emitted from the material could not be reliably detected during the PLQY measurement. To the best of the inventors' knowledge, the previously reported highest PLQY value for any known member of this family of cluster compounds or cluster derivative in solution is 23.8% for [Re₆Se₈(Me₂SO)₆]²⁺ with a PL lifetime of 22.4 μs measured in dimethyl sulfoxide (DMSO) solution. (Gray, T. G. et al., Inorganic Chemistry 1999, 38 (26), 5932-5933; Gray, T. G. et al., Journal of the American Chemical Society 2003, 125 (16), 4755-4770.)

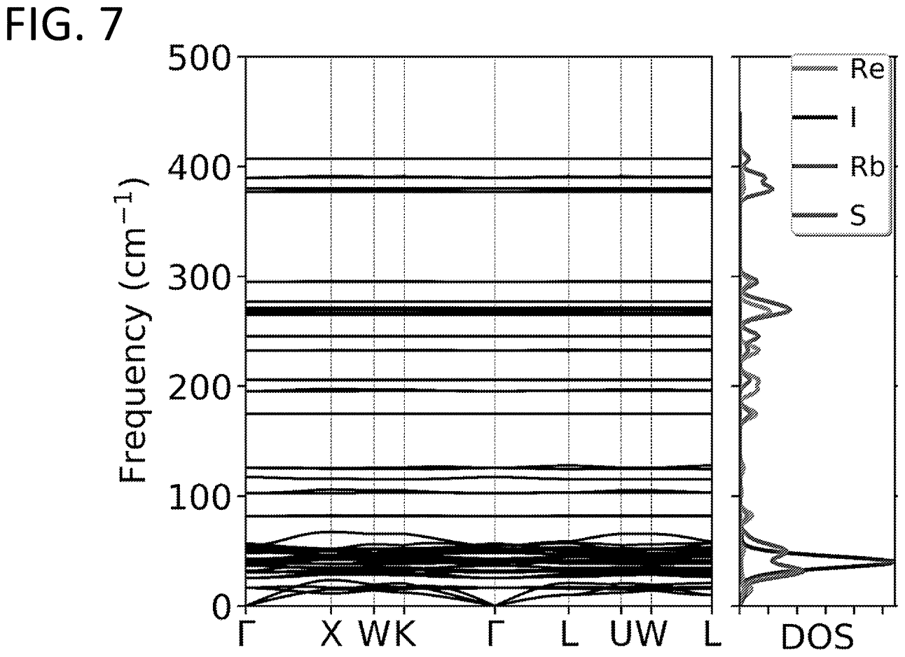

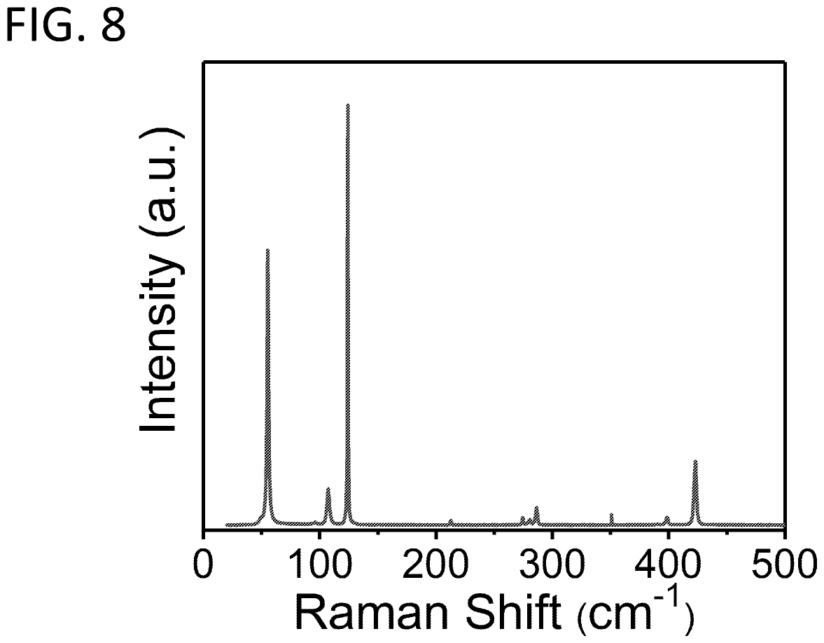

To understand the vibrations in Rb₆Re₆S₈I₈, the phonon modes were calculated, and the phonon dispersion is shown in FIG. 7. It was found that the phonon dispersion had no imaginary frequency, which demonstrates that the structure is dynamically stable at 0 K. Additionally, only the A_{1g}, E_{g}, and T_{2g} are Raman active and only T₁ᵤ is infrared active. It was found that the experimentally observed Raman-active modes shown in FIG. 8 at 55, 107, and 124 cm⁻¹ have good agreement with the calculated low energy Raman-active modes of 50 (T_{2g}), 102 (E_{g}), and 117 (A_{1g}) cm⁻¹ respectively. The small shift is likely caused by temperature which is not included in these calculations.

### Solubility and Cluster Emission in Solution

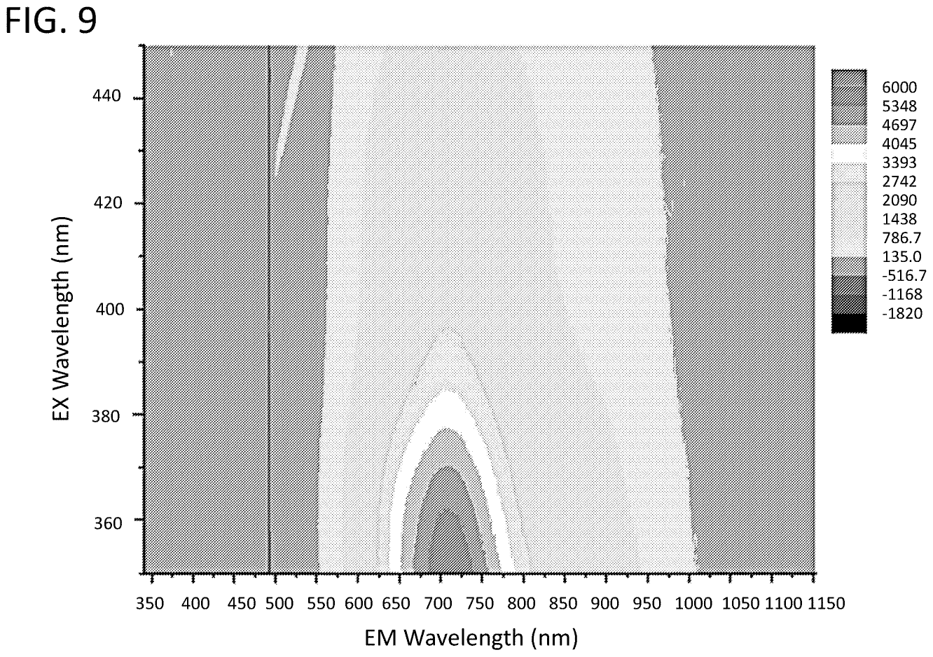

Rb₆Re₆S₈I₈ is soluble in multiple different polar solvents shown in Table 7. Solutions of Rb₆Re₆S₈I₈ dissolved in DMF and in water yield pale yellow-colored solutions which darkened to orange and then dark orange as the concentration increased. The photoluminescence excitation (PLE) was measured for a Rb₆Re₆S₈I₈ solution dissolved in water is shown in FIG. 9 exhibiting the characteristic emission for the solvated [Re₆S₈I₆]⁴⁻ cluster with an emission maximum at 1.74 eV (713 nm) which is slightly higher energy than the emission seen for solid Rb₆Re₆S₈I₈.

TABLE 7
Solubility of Rb₆Re₆S₈I₈.

| More than 0.2 mg/μL | Less than 0.2 mg/μL | Not Soluble |
|---|---|---|
| Dimethylformamide | Acetonitrile | Hexanes |
| N-Methylformamide | Hydroiodic acid | Chloroform |
| N-Methyl-2-purrolidone | Acetone | Toluene |
| Dimethylacetamide | Methanol, ethanol, | Diethyl Ether |
| | isopropanol | |
| Dimethyl Sulfoxide | Puridine | Dichloromethane |
| Water | Ethyl acetate | |

### Solution Processable Films

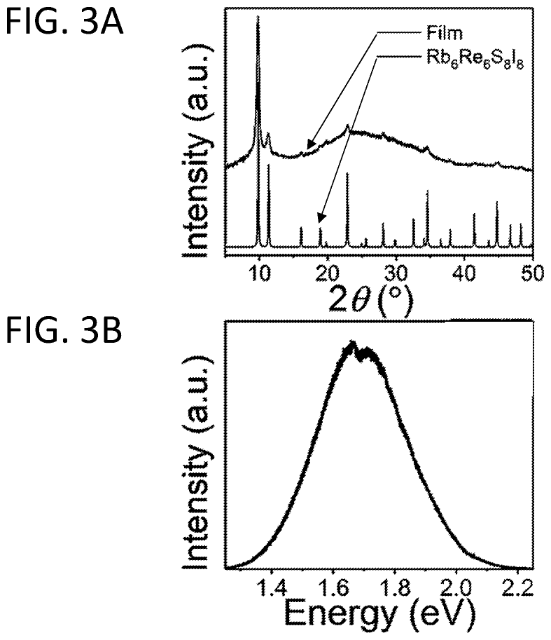

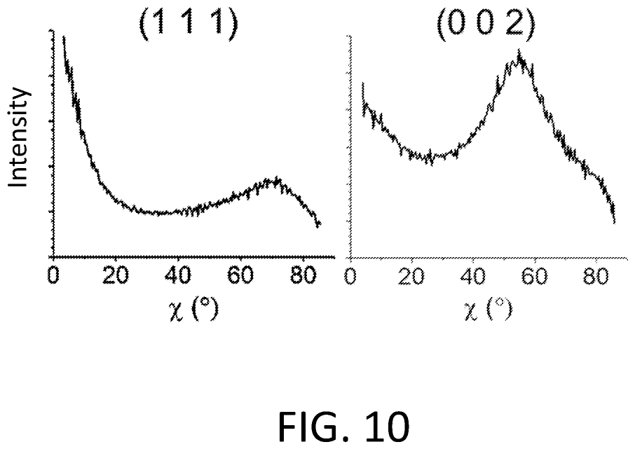

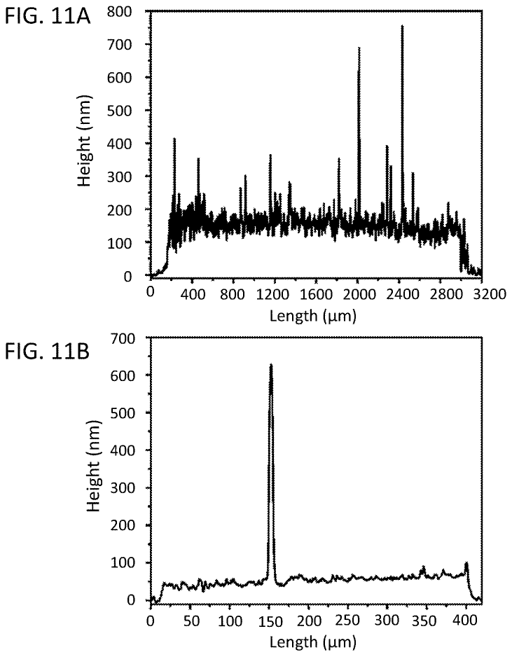

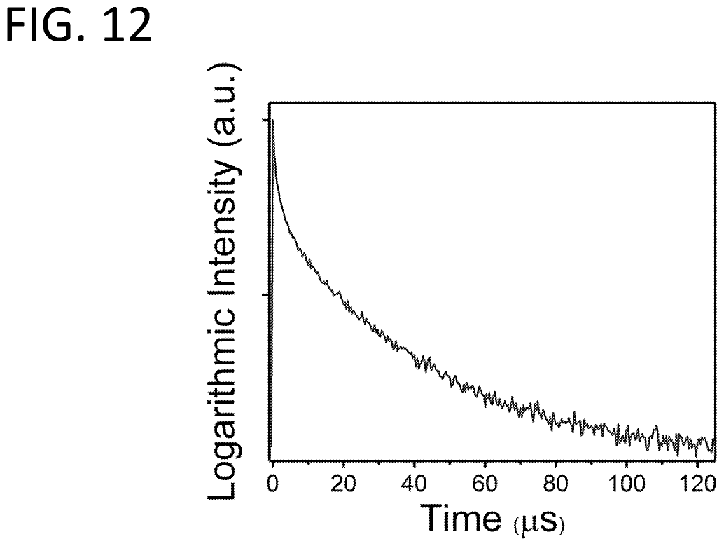

Solution processed Rb₆Re₆S₈I₈ films were fabricated both in air and in a nitrogen glovebox using 0.2 mg/μL Rb₆Re₆S₈I₈ solutions in DMF via one-step spin coating followed by a 30 minute anneal at 150° C. with additional details in the experimental section. For the films cast in air, the PXRD of a typical film is shown in FIG. 3A where all the observed reflections match the calculated peak positions for Rb₆Re₆S₈I₈. The weak and broad feature in the PXRD between ~15° and ~40° 2θ resulted from amorphous diffraction either from the glass substrate or from the Rb₆Re₆S₈I₈ film containing amorphous regions in addition to more crystalline regions. The texture of the film was elucidated by GIWAXS. The patterns, seen in FIG. 10, were mainly composed of rings, indicating that many grains were randomly oriented. That being said, integrating the (002) and (111) peaks over the angular coordinate χ shows that a small population with the (002) peak (FIG. 10, left panel) were parallel to the substrate with a larger significant population of grains oriented with the (111) peak (FIG. 10, right panel) parallel to the substrate. A full explanation of the texture analysis is in the caption for FIG. 10. Profilometry measurements of a typical film cast in air shown in FIG. 11A had an average thickness of 152.7 nm and a roughness of 15.0 nm. SEM images indicated the film surface was a matrix of material with small cube shaped crystallites (<1 μm) both embedded and on the surface of the film in addition to needle-like features. The film also retained the same PL emission range as observed for bulk Rb₆Re₆S₈I₈ shown in FIG. 3B. The PL lifetime is shown in FIG. 12 and required a two-component exponential decay fit with reduced PL lifetimes compared to the bulk unprocessed material. The first component lifetime is 8.75 μs and the second is 30.4 s for an average PL lifetime of a Rb₆Re₆S₈I₈ film as 22.5 μs. These results are likely due to a combination of strain, defects, or reduced crystallinity crystal size in the Rb₆Re₆S₈I₈ film.

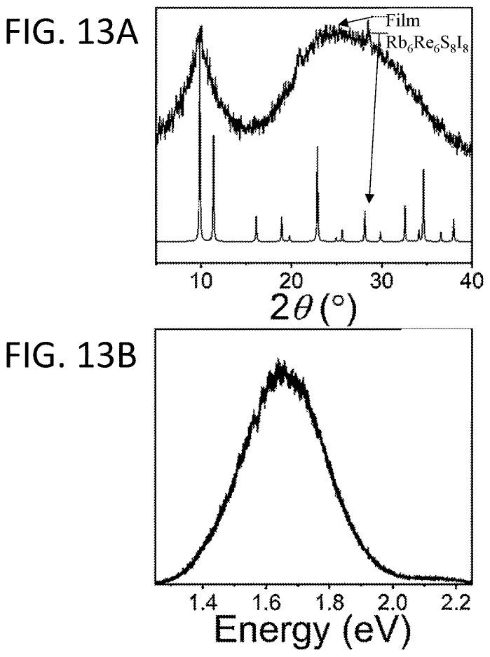

Films cast in a nitrogen glovebox with an otherwise identical procedure were found to exhibit weaker diffraction intensity in the PXRD shown in FIG. 13A attributed to the fact that the films were nearly three times thinner than those cast in air. The observable reflections still indicate phase purity of the films while the PL range was slightly narrower on the high energy side emitting out to 2.00 eV (620 nm) instead of out to 2.15 eV (577 nm) for the films cast in air as shown in FIG. 13B. The profilometry measurements found an average thickness of 59.5 nm and a roughness of 16.7 nm shown in FIG. 11B. SEM images indicated that the films cast in the nitrogen glovebox were a continuous matrix that still had small cube shaped crystallites (<1 μm) both embedded and on the surface of the film but lacked the needle-like features observed for those cast in air.

### Light Emitting Devices

Solution processed thin films of Rb₆Re₆S₈I₈ were used as the active layer of a LED, demonstrating the use of rhenium chalcohalide cluster materials as a solution processable material in optoelectronic devices. The device architecture and band alignment diagram of the constructed LED device is shown in FIG. 4A. Briefly, FTO is used as the transparent contact, PEDOT:PSS as a hole transport layer (HTL), Rb₆Re₆S₈I₈ as the active material, PCBM as the electron transport layer and silver as the second contact with the band alignment diagram shown in FIG. 4B. For the best performing device, as the applied voltage was ramped to 3V, the device emitted strong pink/red light shown in FIG. 4C ranging from 1.20 eV (1030 nm) to 1.85 eV (670 nm) with a maximum at 1.60 eV (775 nm) consistent with the PL emission observed for the bulk material. This demonstrates the ability of Rb₆Re₆S₈I₈ to be used in optoelectronic devices such as light emitting diodes.

### CONCLUSION

Rb₆Re₆S₈I₈ has been characterized as a new solution processable 0D rhenium chalcohalide material containing isolated [Re₆S₈I₆]⁴⁻ clusters crystallizing in the space group Fm3̅m. It exhibits strong and broad room temperature PL in the red to near-IR region with the very long lifetime of 77 s and the PLQY of 42.7% which are longest and largest values for this class of materials. The 0D isolated charged [Re₆S₈I₆]⁴⁻ cluster structure resulted in solubility of Rb₆Re₆S₈I₈ in polar solvents including DMF that enabled solution processing of the material into photoluminescent thin films. Thin films of Rb₆Re₆S₈I₈ were then incorporated as the active layer into light emitting diodes demonstrating the use of rhenium chalcohalides in optoelectronic devices.

### ReS₂ Synthesis

ReS₂ was synthesized as a precursor. Re (0.7438 g, 3.995 mmol) and S (0.2562 g, 7.989 mmol) were mechanically mixed in air in an agate mortar and pestle in a 1:2 stoichiometry. After mixing the reagents, a fused silica tube with outer diameter of 10 mm and inner diameter of 8 mm was charged with the mixture while lined with aluminum foil to prevent powder from sticking to the glass which can prevent the tube from flame sealing properly. The Al foil was then discarded. The tube was then evacuated to a pressure of 4.0×10⁻³ mbar and flame sealed with a methane and oxygen torch. The tube was then placed in a tube furnace and heated to 425° C. in 5 hours, dwelled for 12 hours, then ramped to 850° C. in 5 hours, dwelled for 24 hours, and then the furnace was turned off and allowed to cool to room temperature. Black phase pure polycrystalline powder was obtained.

Rb₆Re₆S₈I₈ Synthesis and Recrystallization

RbI was used as a limiting reagent so that the only soluble species present would be Rb₆Re₆S₈I₈ with the following reaction in mind: 4RbI+2Re+4ReS₂+4.5I₂→⅔Rb₆Re₆S₈I₈+⅔Re+ 4/3ReS₂+3.83I₂. RbI (0.1565 g, 0.4613 mmol), Re (0.0686 g, 0.368 mmol), ReS₂ (0.1845 g, 0.7370 mmol) were mechanically mixed in air in an agate mortar and pestle and charged to a 15 mm outer diameter and 12 mm inner diameter lined with Al foil to prevent powder from sticking to the walls. I₂ (0.2104 g, 0.8290 mmol) was then added on top of the mixture and the Al foil was discarded. The tube was then evacuated until a pressure of 1.0×10⁻² mbar was reached and then cooled with liquid nitrogen for thirty seconds. This condensed the I₂ and prevented it from escaping while having provided time for water vapor and oxygen to have been removed from the tube without condensing in the tube. The tube was then flame-sealed at 3.0×10⁻³ mbar with an internal length of 10 cm. To prevent vapor transport of ReS₂, the sealed tube was positioned in a one zone tube furnace such that the reagents were adjacent to the thermocouple near the cooler outer edge of the furnace while the other end of the tube is in the hotter center of the furnace. To prevent over pressurizing the tube, a theoretical maximum iodine pressure was estimated assuming all of the iodine was a gas at the maximum temperature with 60% dissociation for a maximum calculated pressure of ~10 atm. This is an over estimation as some of the I₂ will dissolve into the molten RbI and react with the I⁻ anions via the reaction I₂+I⁻→I₃⁻. The furnace was heated to 850° C. at a rate of 100° C./hour, held for 96 hours, then water quenched. The product was then ground up and charged to a new tube with the same dimensions along with more I₂ (0.2104 g, 0.8290 mmol) and flame sealed with the same liquid nitrogen procedure as the first time. The tube was then placed in a tube furnace in an identical manner and exposed to the same heating profile and water quench. PXRD was done after the first and second heating step. The product was then ground and allowed to dissolve in 1 mL of anhydrous DMF which was at exposed to air at this point. After 15 minutes the solution was syringe filtered with a PTFE 0.2 μm disposable filter which typically looked darker (almost red/black) than the orange solution (the color of the 0.2 mg/μL concentration solution). This solution was then heated on a hot plate at 110° C. overnight for ~10 hours. Orange product was recovered. PXRD was done of the recrystallized material.

### Powder X-Ray Diffraction

PXRD patterns were taken using a Rigaku Miniflex 5600 powder X-ray diffractometer with Ni-filtered Cu Ku radiation (λ=1.5406 Å) with a 30 kV voltage and 15 mA current. The diffraction pattern scan width was 0.020 and the scan rate was 10° per minute. Simulated PXRD pattern was generated using the Mercury software version 2021.1.0.

### Differential Thermal Analysis (DTA)

DTA was performed using a Netzsch STA 449 F3 Jupiter simultaneous thermal analysis instrument. The sample was loaded into a silica ampoule and flame sealed under vacuum of approximately 5×10⁻³ mbar. An aluminum oxide (Al₂O₃) sample was used as a reference. The sample was heated to 850° C. at a rate of 10° C./min, held for 5 minutes, and cooled back down at a rate of 10° C./min to 200° C., held for 5 minutes, heated to 850° C. at a rate of 10° C./min for a second time, held for 5 minutes, then cooled to room temperature at a rate of 10° C./min.

### Photoluminescence Excitation (PLE)

PLE was measured using a NanoLog spectrophotometer (Horiba Jobin-Yvon). The sample was illuminated by a variable monochromatized light (350 nm to 450 nm), and the photoluminescence spectra was filtered with a 495 nm long-pass filter and was recorded at each wavelength by a CCD with a grating centered at 750 nm (100 grooves/cm, blazed 780 nm). These measurements produced a 3D map of the photoluminescence as a function of the excitation energy.

### Confocal Raman Measurements

Raman measurements at room temperature were conducted on films of single crystal Rb₆Re₆S₈I₈ using a confocal HORIBA LabRAM HR Evolution spectrometer. The excitation wavelength for Raman measurements was 785 nm (1.58 eV) and the laser intensity was 100 mW.

### Photoemission Yield Spectroscopy in Air (PYSA).

The work function which is equal to the valence band maximum energy (VBM) was measured by photoemission yield spectroscopy in air (PYSA, AC-2, Riken-Keiki). In PYSA, the sample is scanned by tunable monochromatic ultraviolet light (UV, 5.00-6.20 eV, step size 0.05), under dry ambient conditions and the number of generated photoelectrons are measured at each excitation energy. Photoelectrons are only generated when the photon energy is higher than the work function. The work function is determined by finding the onset of the PYSA spectra.

### Profilometer Measurements

Film thickness and roughness was measured using the Dektak 150 Stylus Surface Profiler.

### Scanning Electron Microscopy and Energy Dispersive Spectroscopy (SEM/EDS)

Images and quantitative analysis were performed using a Hitachi S-3400 scanning electron microscope that was equipped with a PGT energy-dispersive X-ray analysis instrument. EDS was performed at 15 kV.

### Time Resolved Photoluminescence (TRPL)

TRPL was measured by time-resolved single photon counting (TCSPC), using Edinburgh instruments FS5 spectrophotometer. The sample was excited by 405 nm pulsed laser (EPL405—Pulse width<100 μs), the emission was collected by a fast PMT. The photoluminescence decay was fitted to a multi-exponential function, convoluted with the instrument response function and the average lifetime of the decay were calculated by weighting the different decay components.

### Photoluminescence Quantum Yield (PLQY).

PLQY is calculated by measuring the PL of the sample inside an integrating sphere. To calculate the PLQY, a clean sample holder is measured as reference and afterwards the sample is measured. The scattered photons at the excitation wavelength range are used to calculate the number of photons absorbed by the sample, by comparing the number of photons scattered by the clean sample holder (Ex-Clean) and by the sample (Ex-Sample). The number of emitted photons is calculated by integrating the number of photons emitted by the sample (Em-Sample) subtracted by the noise level (Em-Clean). The PLQY is defined by the ratio of emitted photons and absorbed photons.

$$PLQY ( \% ) = \frac{\# of emittied photons}{\# of absorbed photons} \cdot 100 = \frac{sum ( Em - Sample ) - sum ( Em - Clean )}{sum ( Em - Clean ) - sum ( Em - Sample )} \cdot 100$$

### LED Light Emission Measurement

LED output was measured in a nitrogen-atmosphere glovebox (H2O and O2<1 ppm) using a StellarNet SilverNOVA spectroradiometer coupled with a fiber optic cable to a 6-inch integrating sphere. The spectrometer-integrating sphere system was calibrated using a NIST-traceable calibration lamp. The electrical characteristics of the LEDs were controlled using a Keithley 2400 source-measure unit. The system was controlled using a home-built LabVIEW program to drive the LEDs current, voltage, and spectral output.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A mixed anion rhenium chalcohalide having the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions.

2. The mixed anion rhenium chalcohalide of claim 1, wherein A is Rb.

3. The mixed anion rhenium chalcohalide of claim 2, wherein Q is S.

4. The mixed anion rhenium chalcohalide of claim 3, wherein X is I.

5. The mixed anion rhenium chalcohalide of claim 1, wherein Q is S.

6. The mixed anion rhenium chalcohalide of claim 1, wherein X is I.

7. The mixed anion rhenium chalcohalide of claim 1, wherein the mixed anion rhenium chalcohalide is dissolved in water, an organic solvent, or a mixture thereof.

8. The mixed anion rhenium chalcohalide of claim 1, wherein the mixed anion rhenium chalcohalide is in the form of a solid film.

9. A supported mixed anion rhenium chalcohalide film comprising:
a substrate having a surface; and
a film of a mixed anion rhenium chalcohalide on the surface of the substrate, wherein the mixed anion rhenium chalcohalide having the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions.

10. The supported mixed anion rhenium chalcohalide film of claim 9, wherein A is Rb.

11. The supported mixed anion rhenium chalcohalide film of claim 10, wherein Q is S.

12. The supported mixed anion rhenium chalcohalide film of claim 11, wherein X is I.

13. The supported mixed anion rhenium chalcohalide film of claim 9, wherein the film has a thickness in the range from 50 nm to 1 μm.

14. A light emitting diode comprising:
an electron transport layer;
a hole transport layer;
an active layer comprising the mixed anion rhenium chalcohalide disposed at least partially between the electron transport layer and the hole transport layer, wherein the mixed anion rhenium chalcohalide has the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions;
a first electrically conductive contact in electrical communication with the electron transport layer; and
a second electrically conductive contact in electrical communication with the hole transport layer.

15. The light emitting diode of claim 14, wherein A is Rb.

16. The light emitting diode of claim 15, wherein Q is S.

17. The light emitting diode of claim 16, wherein X is T.

18. A method of forming a mixed anion rhenium chalcohalide, the method comprising:
forming a mixture of two or more chalcohalide precursors, the mixture comprising at least one precursor comprising rhenium, at least one precursor comprising an alkali metal atom, at least one precursor comprising sulfur, selenium, or tellurium, and at least one precursor comprising a halogen atom;
melting the chalcohalide precursors; and
reacting the chalcogenide precursors in the melt under vacuum to form the mixed anion rhenium chalcohalide, wherein the mixed anion rhenium chalcohalide has the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions.

19. A method of forming a mixed anion rhenium chalcohalide film, the method comprising:
forming a solution comprising one or more of the mixed anion rhenium chalcohalides in a solvent;
forming a coating of the solution on a surface of a substrate; and
drying the coating to form a solid film of the one or more of the mixed anion rhenium chalcohalides on the surface of the substrate, wherein the mixed anion rhenium chalcohalide has the formula A₆Re₆Q₈X₈, wherein A is an alkali metal atom, Q is a Se, S, or Te, and X is a halogen atom, and further wherein the mixed anion rhenium chalcohalide comprises [Re₆Q₈X₆]⁴⁻ clusters, A⁺ cations, and X⁻ anions.
